(19) United States
(12) Patent Application Publication
(10) Pub. No.: US 2005/0204939 A1
(43) Pub. Date: Sep. 22, 2005

(54) Three-dimentional components prepared by thick film technology and method of producing thereof

(76) Inventor: Jan Krejci, Kurim (CZ)

Correspondence Address: NOTARO AND MICHALOS, 100 DUTCH HILL ROAD, SUITE 110, ORANGEBURG, NY, 10962-2100, US

(21) Appl. No.: 10/516,161

(22) PCT Filed: Jun. 2, 2003
(86) PCT No.: PCT/CZ03/00031

§ 371 Date: Nov. 30, 2004

(30) Foreign Application Priority Data
Jun. 3, 2002 (CZ) PV 2002-1926

(51) Int. Cl. B81B 1/00; B81C 1/00

(52) U.S. Cl. 101/129; 101/114

(57) ABSTRACT

Object of the present invention are components with three dimensional structure prepared by thick film technology by print, where between the printed layers is inserted at least one membrane. The membrane is according to the present to invention at least in a part of the final product. The membrane can be provided with holes which are necessary for next technological steps. The inserted membranes can have pores of the size of 50˜tm to 10 nm and a thickness of 1 to 200˜tm. Method of producing of components with three-dimensional structure by thick film printing technology according to the invention lies in that between some of the printed layers is inserted a suitable membrane, which allows to lay on next layers without influence to previous layers. The printing can be done by screen-printing.

### TECHNICAL FIELD

The invention relates to three-dimensional components prepared by thick film technology and method of preparing thereof.

### BACKGROUND ART

The thick film technology is a technology of creating two dimensional structures by printing followed by curing. The most used type of printing is the screen-printing. Plug printing and jet-printing are also rarely used. Hardening is usually carried out by firing which removes volatile components that provide good technological properties of printing. Hardening of layers is possible by drying at normal or slightly higher (60-150° C.) temperature when using polymer pastes.

Thick film technology is most of all used in electronics for special electronic circuits production. Conducting nets, resistors and capacitors are produced by paste printing on a corundum pad. The pastes contain a base organic part and active metal or dielectric material.

The decomposition of organic matrix and bond of active component on a pad occurs by controlled firing. Active electronic components are post inlaid into the circuit and connected to the conducting net. (M. R. Haskard & K. Pitt: Thick film Technology and Applications, Electrochemical publications Ltd. 1997).

Classical materials of thick film technology are latterly supplied by materials where the carrier of the active component ensures adhesion and strength of a printed layer. There are known materials that are able to be hardened by heat or UV radiation.

Recently the thick film technology is widely used for sensors production. There are many types of sensors produced by thick film technology. Particularly there are temperature and pressure sensors. A very broad field for the application of thick film technology is in the area of chemical sensors. The main advantage is the possibility to lay on very small quantities of substances in a very reproducible way. There is no technical problem to apply quantities down to 10 μl (approx. 10 μg).

This fact enables the use of expensive chemical substances such as enzymes, antibodies, DNA segments etc. Thick film technology makes it possible to use such little amounts of these substances that the price of the final product is not much influenced by the cost of chemicals.

On the other hand using small quantities of chemicals means to measure very small signals. The further advantage of the thick film technology is the possibility to integrate the evaluating electronic unit very close to the measuring place and thus to measure very small signals (for example Overview of chemical sensors, G. Huyberechts, Imec 1995, Brno 1995, Sensors and sensors systems).

An example of known chemical sensors that are produced by thick film technology are glucose sensors (patent EP 078636, WO 97/02487, U.S. Pat. No. 5,762,770, CA 2 224 308, WO 99/30152) and biosensor substrates (CZ patent applications PV 864-94, PV 3780-96). Many types of sensors are described in the literature (e.g. Biosensors, Fundamentals and Application, edited by A. P. F. Turner, I. Kraube & G. S. Wilson, Elsevier Advanced Technology, Ltd.).

The main disadvantage of all these chemical sensors is that there is no possibility to integrate complicated chemical processes. In many of these determination a sample preparation is needed—filtering, separation, reacting substances adding. The chemical sensor must contain not only electric conducting pathways, but even conducting pathways for chemicals and their solutions.

There are made attempts to create these structures both by LTCC (Low temperature co-fired ceramic) (Etching and Exfoliation techniques for the Fabrication of 3-D Meso-Scales Structures on LTCC Tapes, J. Park, P. Spinoza-Vallejos, L. Sola-Laguna and J. Santiago-Aviles, Proceeding of IMAPS'99, San Diego, USA 29 Oct.-3 Nov. 1998) and by sticking the upper layer on the sheet shape channel (Thick Film Microchannels: Design and Fabrication, D. Filippini, L. Fraigi & S. Gwire, Microelectronics No. 40, May 1996). The disadvantage of the first example is the high technological requirements and difficult production of more complicated structures. The disadvantage of the second one is the low reliability of the sticked parts and the inflow of the glue into the sensor's active structure.

The disadvantages of known solutions are overcome by the three-dimensional components prepared by thick film technology and screen printing and method of their production according to a presented invention. The known solutions are mostly on the level of basic research and first experiments. Their common disadvantage is their demanding large-scale production and in many cases their price. The disadvantage of known methods e.g. micro-cut needs a long time of preparation and the necessity of expensive machines, etching is time consuming and the technology is expensive, laser-cut is very expensive and the monolithic technology is a very costly technology. The geometrical limits are too low for the application in microsensors with fluidic circuits.

### DISCLOSURE OF INVENTION

The object of the resent invention are three-dimensional components prepared by thick film technology that have at least one membrane sandwiched between printed layers. According to a further embodiment of the invention the membrane is being at least in a part of the resulting product. According to a further embodiment of the invention the membrane is provided with holes that are necessary for following technological steps. The inserted membranes can have pores having a pores size of 50 μm to 10 nm and a thickness of 1 to 200 μm.

The method of producing three-dimensional components by thick film technology and printing according to the invention lies in inserting an appropriate membrane between the printed layers. The membrane enables it to apply further layers without influencing previous layers. Printing can be carried out by screen-printing.

The inserted membrane can be produced from the same material as the applied layer matrix binder. In this case the membrane is during technological process removed by heat just like the matrix of paste itself and membrane is not present in all parts of resulting product. It can also be produced from a material which can be chemically decomposed and the membrane is then not present in all parts of resulting product. As membrane which can be decomposed by heat there can be used for instance a membrane made of cellulose acetate having pores with a diameter of 1-0.001 μm and a thickness of 0.1-50 μm.

The inserted membrane can be prepared from an inert material and then it stays present and fully functional after all the technological steps are finished. An appropriate membrane is for instance prepared from polyethylene terephthalate perforated by neutrons having pores of a diameter of from 5 to 0.05 μm and a thickness of 2-20 μm.

Basic requirement for membrane is the porous structure that is optimally designed owing the material characteristics of the used printing paste. The paste must penetrate to the membrane structure consequent on surface tension. But it must not flow out of the membrane. Under these conditions can be achieved a compact three-dimensional complex which can contain channels, filters and mixing elements, and perhaps further active elements.

The membrane can be inserted even pre-shaped or prepared with through holes and supplementary holes. The porous structure of the membrane can be present only in the part connected directly with the printed layers. Such a membrane is prepared from compact nonporous material that is at contact site of the membrane and the printed layer performed so the minimum holes distance is smaller than fivefold the printed layer thickness. Metal is a possible membrane material.

By the word “components” are in the present invention designated sensors, elements and modules creating a basic part of the device described in the examples. The original method of production of these devices comprising particular layers printing and their motives are shown in the attached drawings.

### BRIEF DESCRIPTION OF DRAWINGS

The invention is illustrated in attached drawings.

FIG. 1 shows schematic follow-through filter production technique,

FIG. 2 shows the resulting microfilter prepared in the way of FIG. 1,

FIG. 3 shows the capillary electrophoresis with conductivity detection,

FIG. 4, shows a microdialyzing unit and

FIG. 5 the production thereof,

FIG. 6 shows the production technique of a sensor for chemical reaction kinetics measurement,

FIG. 7 shows the way for an exactly defined reference electrode,

FIG. 8 shows the way for planar oxygen electrodes,

FIG. 9 shows the electrode production for an electrocardiograph with gel,

FIG. 10 a gas flow meter,

FIG. 11 a liquid flow meter,

FIG. 12 a capacitive pressure sensor,

FIG. 12 a capacitive microphone,

FIG. 13 acceleration sensors,

FIG. 14 active part of membrane pump,

FIG. 15 a backward valve,

FIG. 16 a membrane pump and on

FIG. 17 a capillary electrophoresis on Si chip, with sample preparation,

FIG. 18 shows the way of producing a microchemical reactor,

FIG. 19 shows the way of producing a mercury microelectrode and

FIG. 20 shows the cross-sectional view of the mercury electrode.

### EXAMPLES

### Examples of invention performance are completed by Figures that in most cases consist of two parts: template shape that is used for printing and is situated in the left part of the picture; the whole product arrangement after corresponding printing or membrane inserting that is situated on the right and is displayed as sheet or in a cross sectional view.

### Example 1

Flow Through Filter Produced by Thick Film Technology

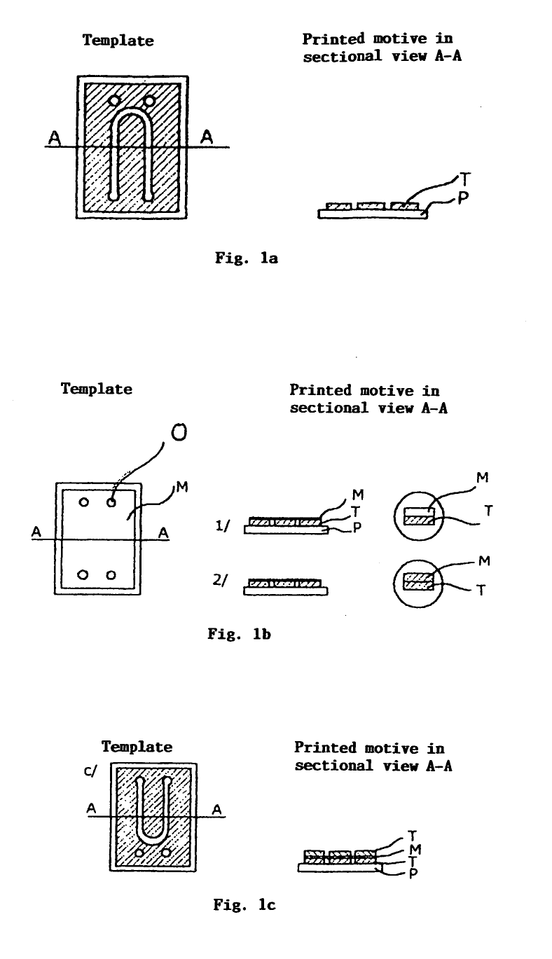

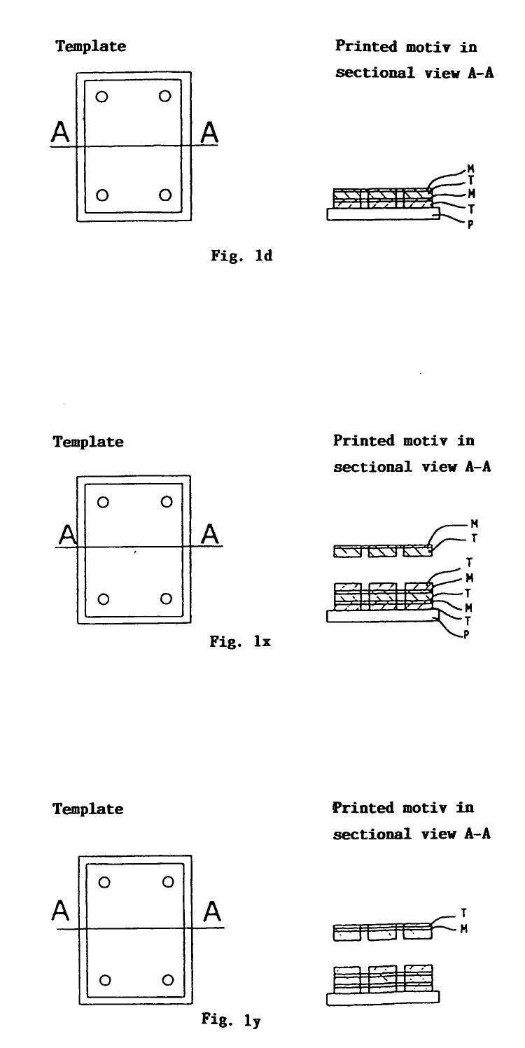

The flow through filter production steps are described in FIGS. 1a to 1y. Layer T that create the channel for filtered liquid input and a collecting channel for a filtrate output is printed on a ceramic pad P in the first step (FIG. 1a). There is used e.g. a polymer paste Du Pont 5483. The width of the channel is 250 μm, its height is 15 μm.

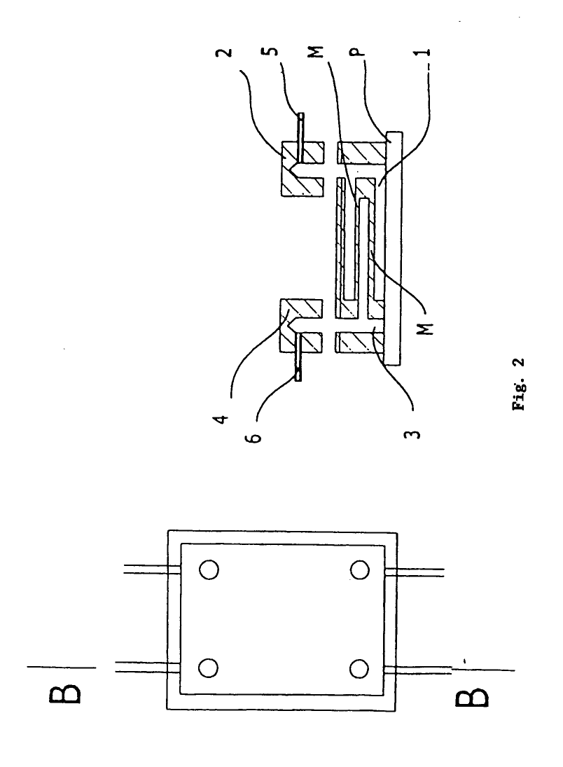

On the non-hardened print of the previous layer is put a porous membrane M produced from polyethylene terephthalate neucleopor with 1 μm pores and a thickness of 10 μm (see FIG. 1b-1). The membrane has four holes O for liquid inflow and filtrate output. Owing to a surface tension is the paste partly sucked in the membrane at the contact sites between the membrane and paste (FIG. 1b-2) and a homogenous connection with the printed layer T occurs. The channel is closed and the pores stay free.

In the third step (FIG. 1c) the channel for filtrate output and channels for liquid inflow is printed. In the fourth step (FIG. 1d) the membrane M is inserted just like in the second step (FIG. 1b).

The steps are repeated till the optimal number of layers is achieved. The production process is finished by inserting the last membrane M (FIG. 1x) on which the closing layer is printed in step y. The unit is fully cured by heating at 200° C. for 20 minutes. The input for liquid and the filtrate outlet are sticked on.

The arrangement of the resulting microfilter is displayed on FIG. 2.

The liquid flows in a jet guide 3 through an input mouthpiece 6 from where it goes through particular channels provided with membranes M. The filtrate that went through the membrane is drained into a collecting channel 1 from where it is lead to the output mouthpieces 5. The input and output mouthpieces are tightened in holders 4 and 2.

Resulting parameters: dimensions 10×20 mm, active layer thickness 1 mm, active membrane area 50 mm², input and output pipe diameter 1 mm.

### Example 2

Capillary Electrophoresis with Conductivity Detection

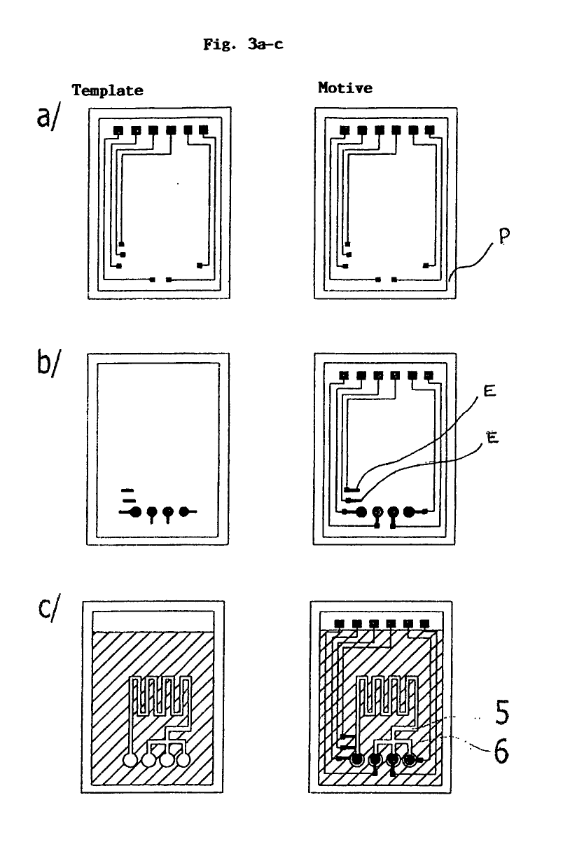

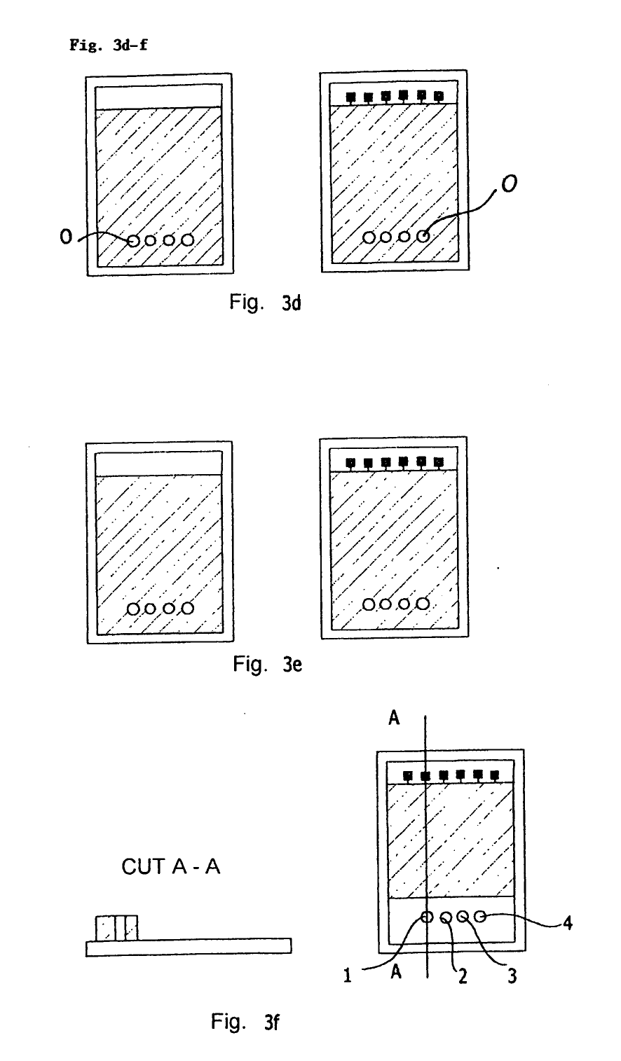

The production technique is shown in FIGS. 3a to 3f. Basic conducting links motive are printed on a corundum pad P in the first step using for example Ag conducting paste Tesla 9220 (FIG. 3a). The electrodes for electrophoresis and conducting detector electrodes E are printed in the next step using for example Au paste Du Pont 4140. The substrate is fired at 850° C. and the basic electric net formed. The channel structure 5 is printed using a dielectric paste (Du Pont 5483, for example) in the step figured in FIG. 3c. The appropriate channel side walls height is achieved by repeating this step. The membrane from polyethylene terephthalate nucleopor with 1 μm pores and thickness of 20 μm is inserted in the step figured in FIG. 3d and it is provided with holes O. The production is finished by printing the upper covering layer (FIG. 3e). Whole system is cured at 200° C. for 20 minutes. The entry part for easier sample applying is sticked on (FIG. 3f).

System is filled with a gel.

Function: Sample drop is deposited into a hole 2. The sample starts moving from hole 2 a 4 through channel 6 after connecting golden electrodes in the entries 2 and 4 to high voltage in consequence of electroosmotic flow. Zone originates at crossing place of capillaries. Zone electrophoresis occurs from crossing on capillary between 1 and 3 after switching a high voltage on. Continuity of particular divided zones is detected by a conducting detector.

### Example 3

Microdialyzing Unit with a Biosensor

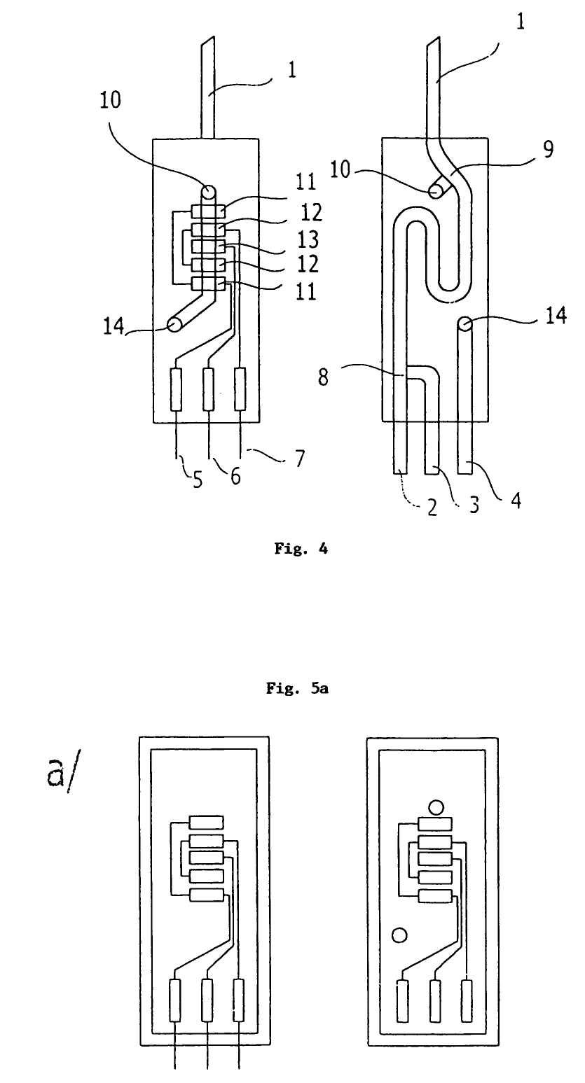

The production process according to the invention can be used with advantage for construction of microdialyzing unit for continual blood analyzis by biosensor. The schema of the unit is on the FIG. 4. Directly to the injection needle is integrated a miniature system of the size 25×7 mm, which contains three electrode amperometric biosensor and dialyzing cell, which allows the separation of plasma from the blood and its dilution. Blood is inputting to the sensor by injection needle 1 inserted to the patient's vein. Than it runs through the channel created in the way according to the invention, whereby from point 9 till point 8 the channel bottom is formed by a half penetrating membrane. Blood is lead away by mouth piece 2. Dialyzing liquid enters at point 3 and is lead through the channel, the ceiling of which is in the part signed 8 and 2 common for the channel bottom for blood. This is a point where dialysis of low molecular weight species penetrate from blood to the dialyzing solution. The dialyzing solution flows through a hole 10 on the other side of the substrate, where it is analyzed by an amperometric enzyme detector, which consists of a pair of reference electrode 12 and a working electrode 13 covered by enzyme. The dialyzing solution flows to the other side of the chip through the gap 14 and it is going out from sensor through output 4. The electrodes are connected by contacts 5, 6, 7.

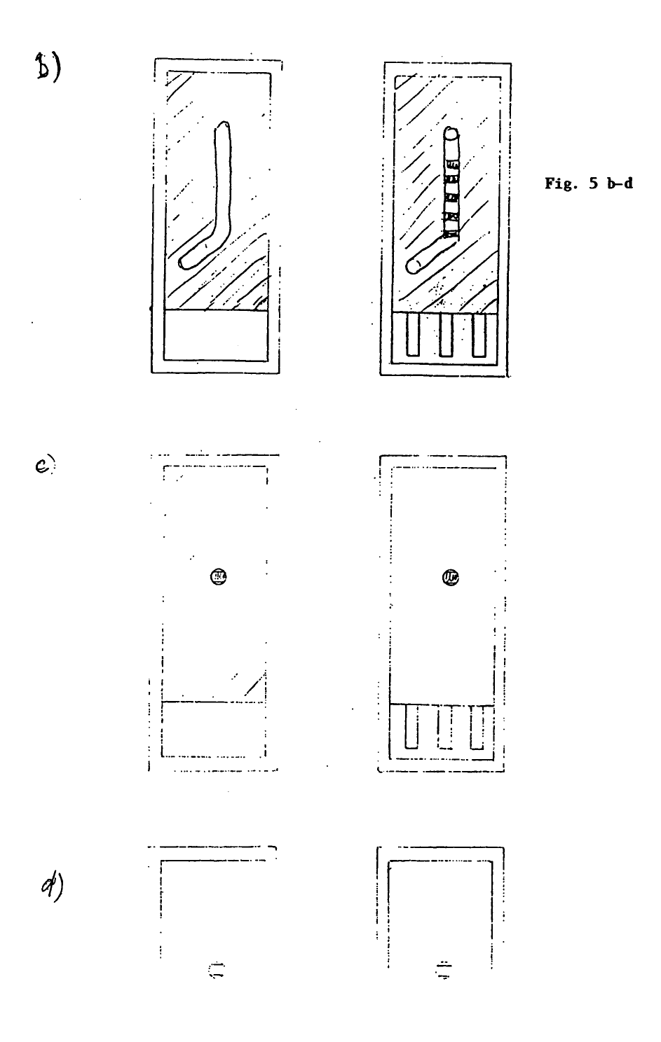

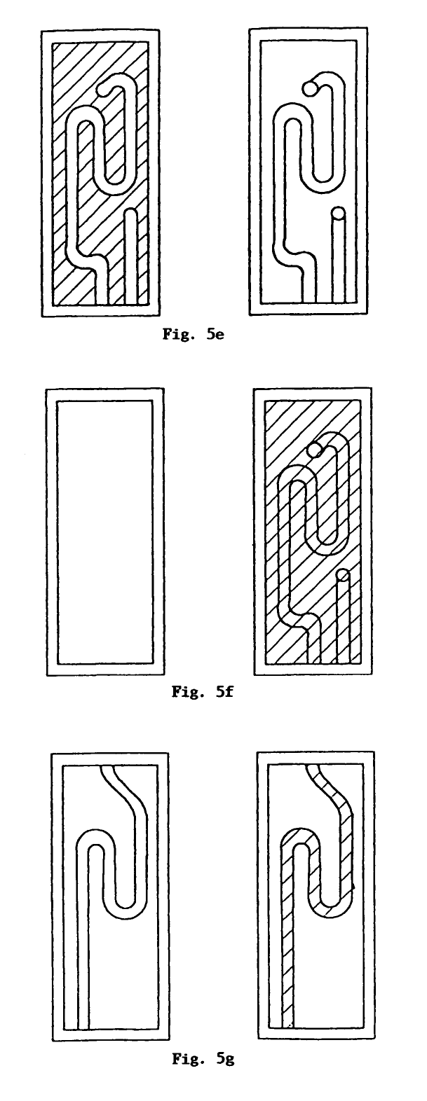

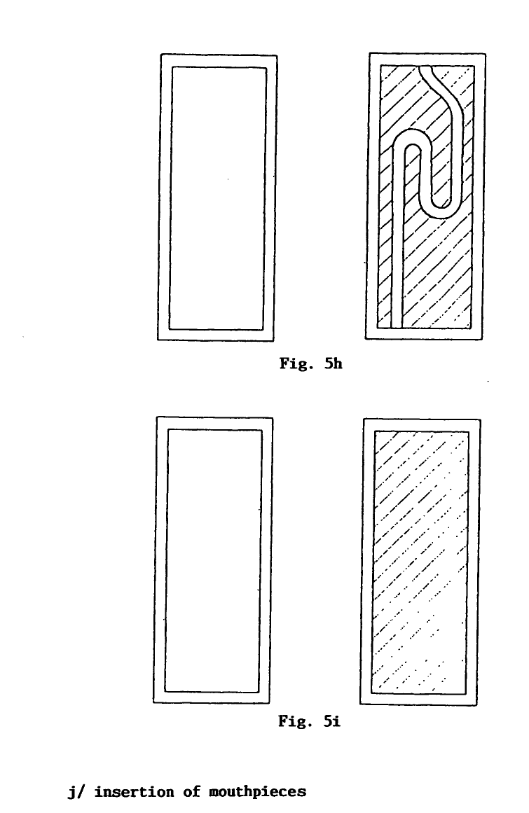

The production process according to the invention is presented on FIG. 5. First of all a structure of conducting circuits and measuring electrodes on ceramic substrate with two holes is printed (FIG. 5a). The basic shape of microchannel, which defines electrodes working area in a flow arrangement is printed in the next step (b), (FIG. 5b). The next step (c) uses the invention and a polyethylene terephthalate nucleopor membrane is inserted, which has 1 μm pores dimension and a thickness of 20 μm with a hole above the working microelectrode (see FIG. 5c). The cover layer which will create ceiling of flow little channel is printed. The gap above the working electrode is prepared for laying of enzyme and closing of microchannel. The unit is cured. The next technological steps are done on the opposite side of the substrate.

The channel structure between two through holes, through which is running the dialyzate is printed in the step (e) (FIG. 5e). The membrane (FIG. 5f) prepared of acetate cellulose (Cuprophan PM 150) with a thickness of 15 μm is laid in the next step (f).

The channel for blood is printed in the step (g) (FIG. 5g) and is over covered by a membrane of polyethylene terephthalate nucleopor with a pore size of 1 μm and a thickness of 20 μm in the step (h) (FIG. 5h).

The compact ceiling of structure is created in the step (i) by printing of covering paste. The production is finished by inserting a needle for input to the vein and mouthpiece for input and output of dialyzate and blood drainage (FIG. 5j). Due to the option of channel height and width it is possible to set dilution ratio of dialyzed blood. By the laying of enzyme and by sticking of prepared window the production is finished.

### Example 4

Sensor for Chemical Reaction Kinetic Measurement

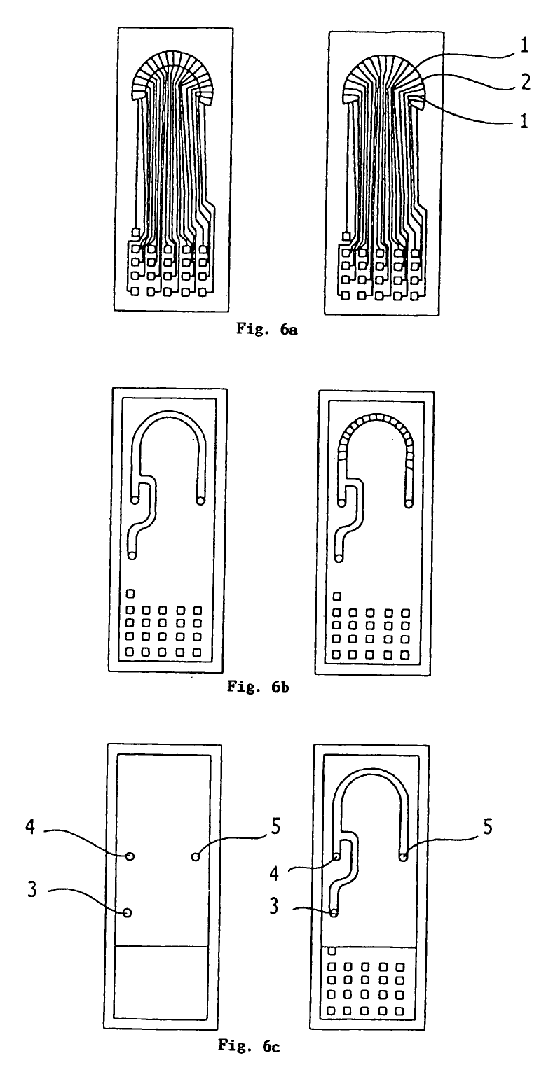

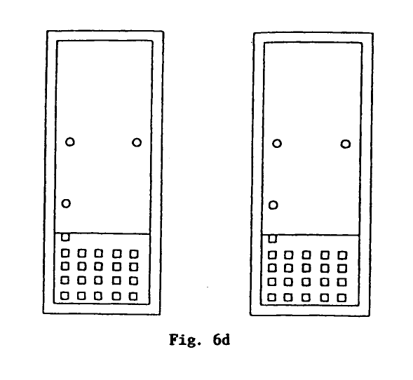

The structure of electrodes is printed in the first step (a). The structure is made of the field of working and reference electrodes (FIG. 6a). The structure of channel is printed in the next step (FIG. 6b). It both allows the mixing of two measured solutions and defines the field of working electrodes. The membrane of polyethylene terephthalate nucleopor with pore size of 1 μm and a thickness of 20 μm with three holes is laid in the step (c), which will serve for the input of reaction samples and output of the mixture.

The whole system is over covered by a covering layer in the step (d), thereby microchannels, liquid inputs and outputs are finished.

In the flow arrangement, the sensor is directly measuring the timing of the reaction kinetic.

### Example 5

Exactly Defined Reference Electrode on a Two Dimensional Sensor

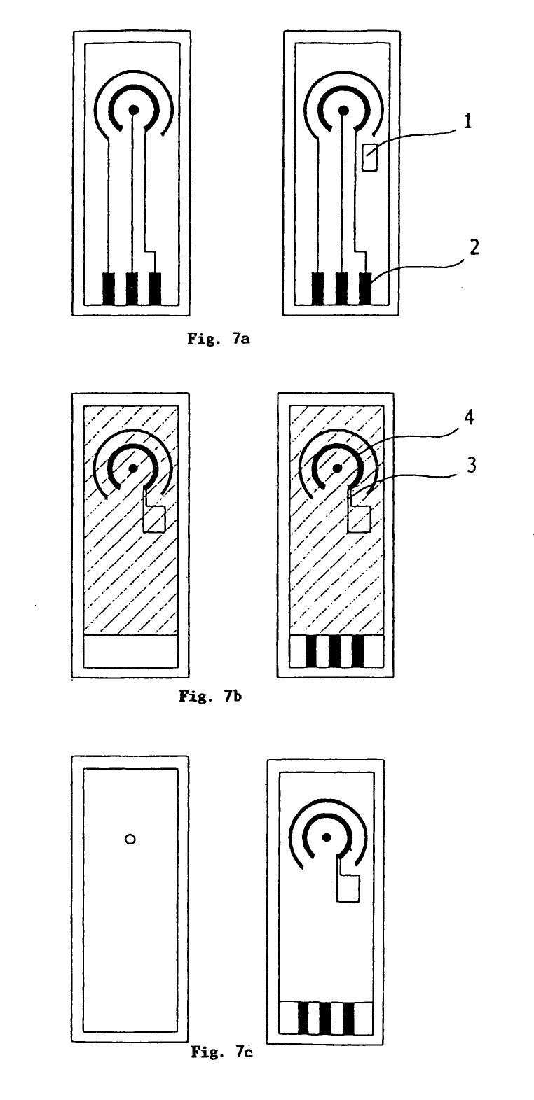

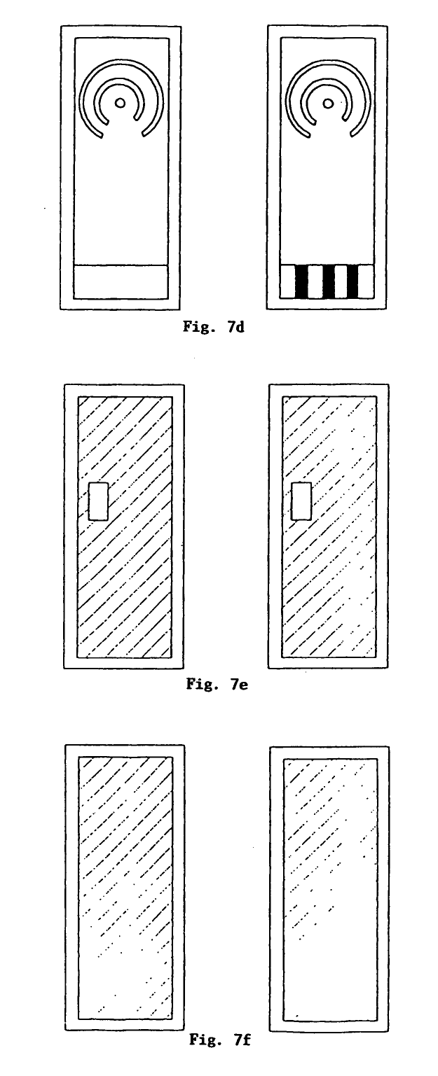

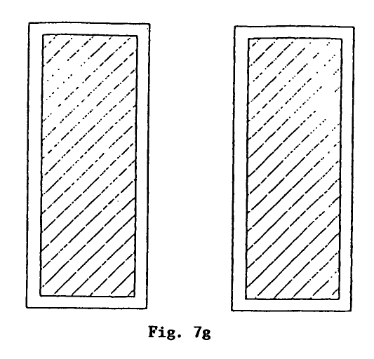

Basic electrode structure (FIG. 7a) is printed on substrate with cut-out reservoir (see FIG. 7). Microchannel for connection of reference electrode with a reservoir of inner electrolyte is made in the next print (b). Membrane of polyethylene terephthalate nucleopor with pores size of 1 μm and a thickness of 20 μm with cut-out hole for working and auxiliary electrode is placed in the next step (c) (see FIG. 7c).

The print of another structure is done in the step (d), which will harden the ceiling of channel connecting reference electrode with electrolyte reservoir and fasten the membrane in the place of liquid connection of reference electrode and measured sample.

After curing the substrate is turned over. The layer which allows the creating of ceiling above an inner electrolyte reservoir of reference electrode is printed in the step (e). After that is to the reservoir put a mixture of KCl and CaCl₂. Membrane of polyethylene terephthalate nucleopor with pores size of 1 μm and a thickness of 20 μm is laid in the next step (f) (FIG. 7f) and the cover layer is printed out (FIG. 7g). After filling up the sensor with water (for example submersing to water and pressure increasing and decreasing) the sensor is ready to measure.

### Example 6

Planar Oxygen Electrode

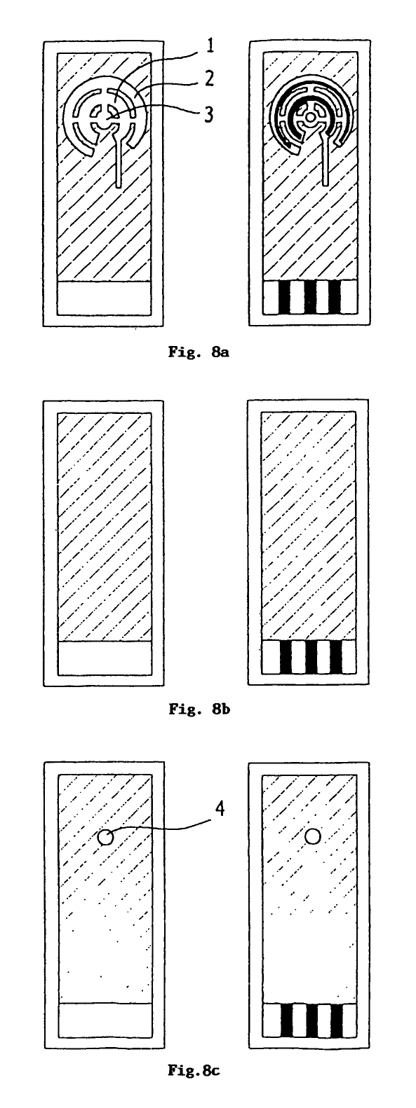

The process of production is quite the same as in the example 5. The only difference is that in the points b, c and d are used different motives of print, which are demonstrated at the FIG. 8. A structure, which allows the electrolyte to pass to the three areas—reference electrolyte area, supporting electrode area a working electrode area is printed in the step (b). Membrane is laid in the next step (c) (FIG. 8c). It has no holes. The structure is closed by printing the covering layer, which defines input window for oxygen input. Filling up by electrolyte and finishing of electrolyte reservoir is done in a similar way as in the example 5 only with the difference, that the electrolyte reservoir is filled with liquid at first and after that its input is closed by sticking.

### Example 7

Electrode Production for Electrocardiograph with Gel

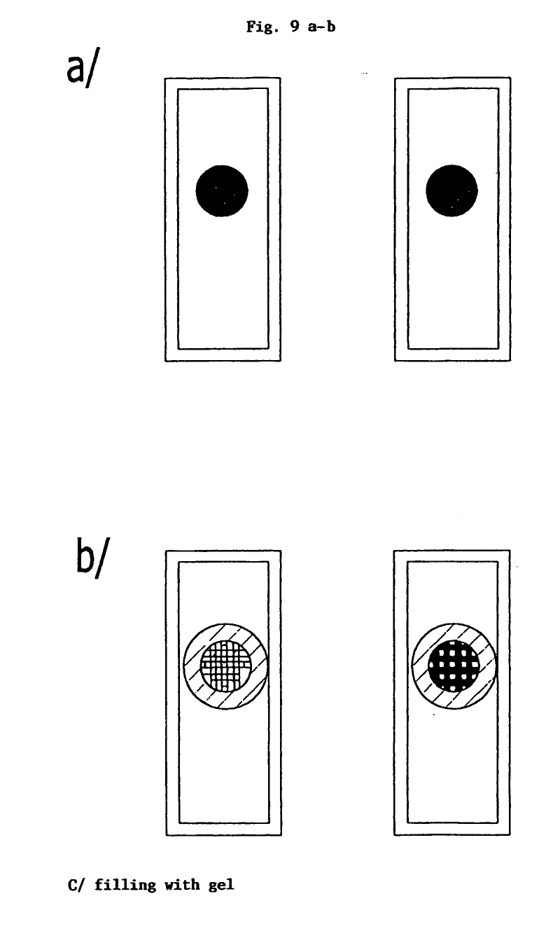

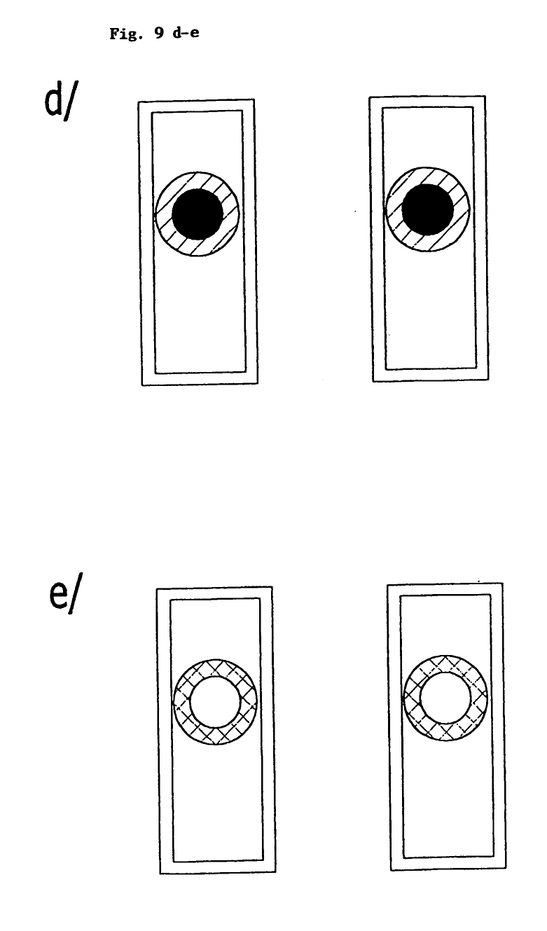

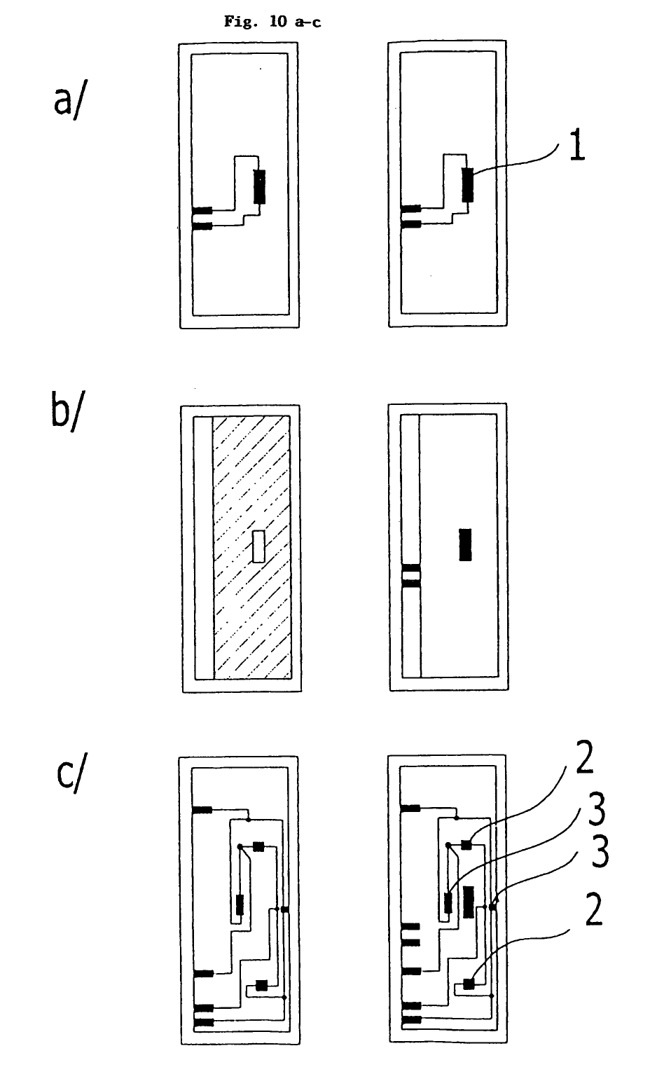

First of all the layer Ag/AgCl is printed on the plastic pad with a contact (FIG. 9a). Auxiliary layer is printed for consolidation of membrane in the next step (b). The structure is filled up with gel (step c) and in the step (d) the membrane with a thickness of 15 μm (for example of Cuprophan PM150) is laid on (FIG. 9d). The membrane is fixed by the printing of the last layer in the step (e) (see FIG. 9e).

### Example 8

Gas Flow Meter

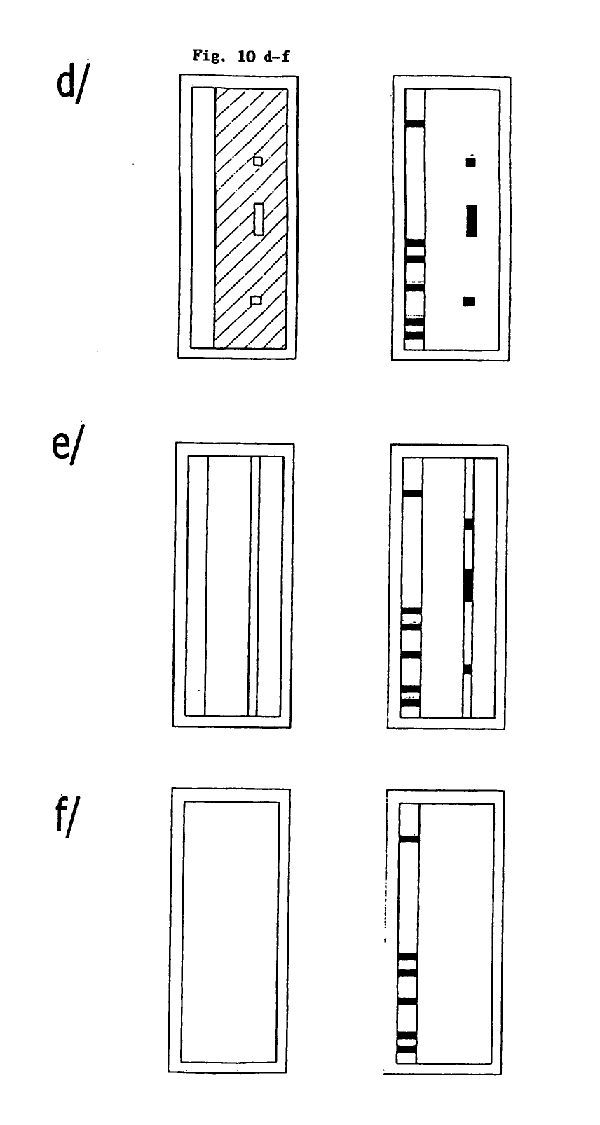

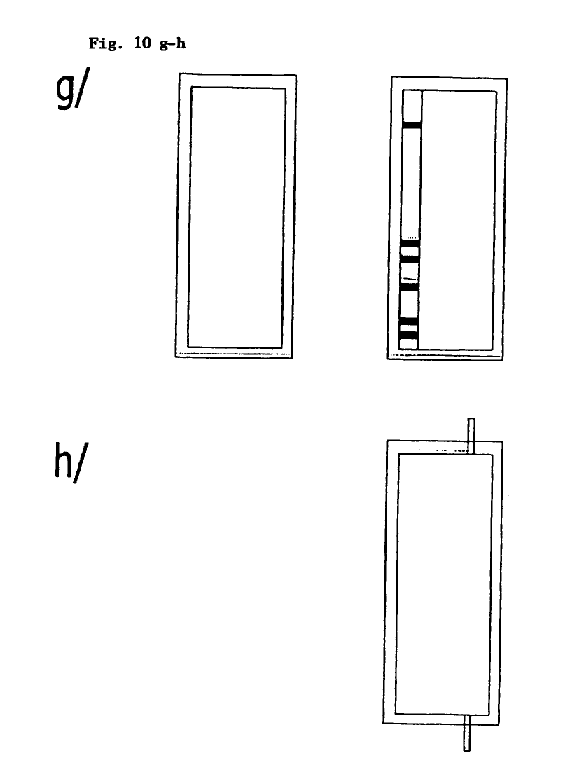

The first conductive structure, which is composed of conductors and heating element 1 is printed in the first step (a) (see FIG. 10a).

Compact ceramic layer made of dielectrical paste is printed in the next step (b) (FIG. 10b). The complex is burnt out and ready for printing of measuring bridge. The measuring bridge is created by conductors network and thermistors prepared by the print of thermistor paste. The network creates Wheaston's bridge, where resistances 2 are influenced by flow of gas and the resistances 3 are not influenced by gas flow. In the next step (d) the resistant network is covered by dielectrical layer in the way that: only measuring thermistors and heating resistance are opened (FIG. 10d). The microchannel is created according to the invention in the next step. First of all the side walls of the microchannel are printed (step 10e) In the next step a membrane of polyethylene terephthalate nucleopor with a pores size of 1 μm and a thickness 20 μm is laid on (step 10f). It is overlaid by final print (steplog) which creates the ceiling of the channel. The product is finished by inserting the mouthpieces. The function principle is based on non-symmetrical heating due to gas circulation. One thermistor is cooled and the other one is heated. The unbalance of the bridge is proportional to the gas flow.

### Example 9

Liquid Flow Meter

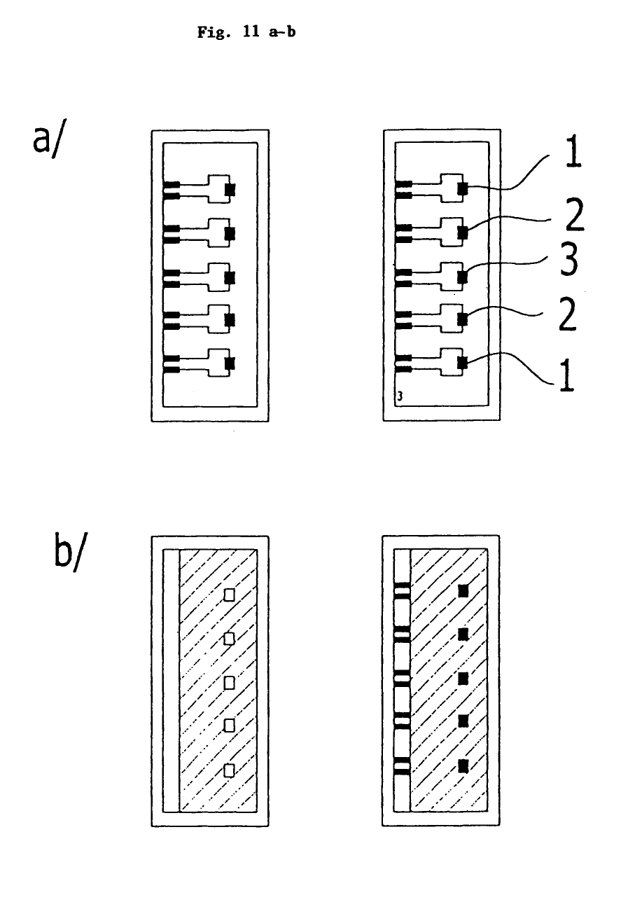

The principle of liquid flow meter production is analogous to the previous example. In the first step conductors, thermistor (2, 1) and heating resistance 3 network are printed (see FIG. 11a). The structure is laid over by a dielectric layer, so the active elements are protected against direct liquid influence. The measuring bridge is prepared in the same way as in the case of gas flow meter (see FIG. 10, steps c-h).

The function principle: current pulse which is lead to the exciting heating resistance (3) is going to create a zone with higher temperature in the liquid. This zone caused by temperature pulse is transferred to the first thermistor 2 and then to the second 1. It is possible to set the liquid flow because of the known distance of thermistors (2 and 1), channel profile and timing of passage of temperature pulse between the thermistors 1 and 2.

### Example 10

Capacity Pressure Transducer

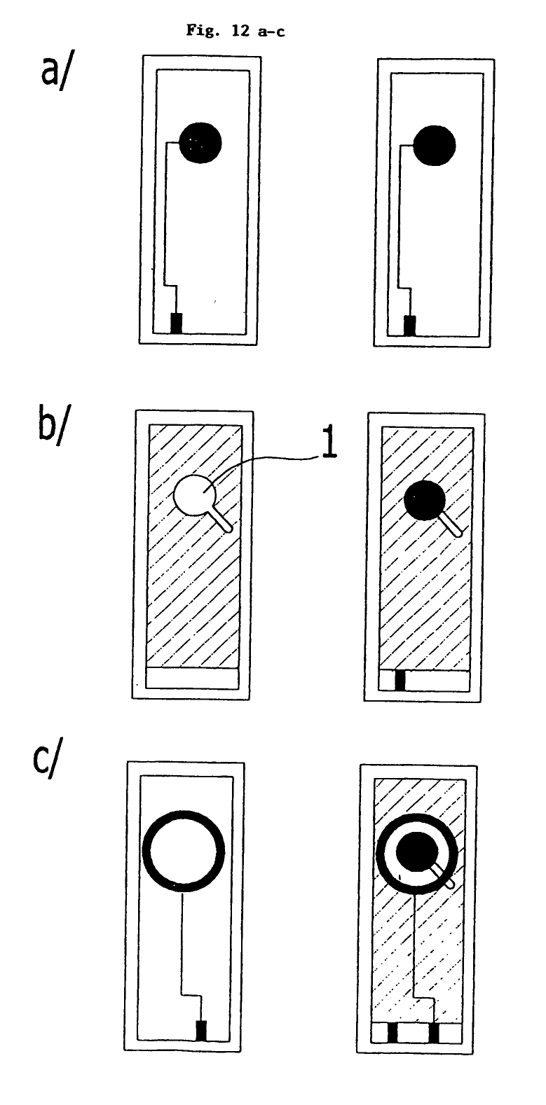

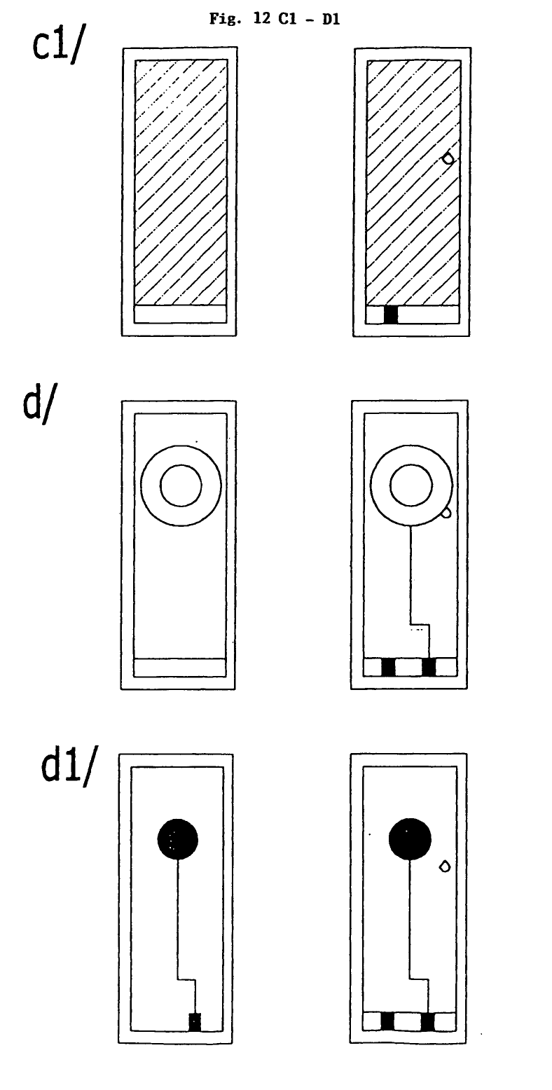

The process of the capacity pressure transducer production is on FIG. 12. The conducting structure with a first electrode of measuring capacitor is printed in the first step (a) (see FIG. 12a). In the second step (b) the supporting layer of membrane from dielectric paste is printed. At the same moment also deaerating channel is printed (FIG. 12b). In the third step there are two production possibilities. Conductors in the shape of layer annular ring are printed (FIG. 12c). Optionally the membrane for example from polyethylene terephthalate nucleopor with a pores size of 1 μm and thickness of 20 μm is put on the green layer printed in the step 12b (FIG. 12c1). In the fourth step metal membrane made of nickel having a thickness of 5 μm is laid on the green conducting paste (FIG. 12d). This membrane perforated according to the invention is in contact with a green paste (FIG. 12d). Optionally a polymer membrane for example from polyethylene terephthalate nucleopor with pores size of 1 μm and a thickness of 20 μm is placed on the layer printed in previous step and reprinted by conducting paste (see FIG. 12d1). The capacity transducer is finished by printing of the last covering layer. Deaerating channel serves to compensate the pressure during the production. When the whole sensor is tempered, the channel is blinded and transducer is ready for work.

The process of production with the use of polymer membrane is suitable for cheap pressure sensors with lower life time. The procedure with inserted metal membrane is more suitable for sensors with higher quality and longer life time.

### Example 11

Capacitance Microphone

If the procedure according to the example 10 is used (FIG. 12) with the exception of the step d where a metal membrane is inserted (for example nickel foil with a thickness of 5 μm, which is sufficiently thin and in the final operation the hole for pressure compensation is not closed), it is possible, when its diameter is sufficiently large, to reach the state that the pressure change caused by influence of noise trembling will be detected. The capacitance microphone arises.

### Example 12

Acceleration Sensor

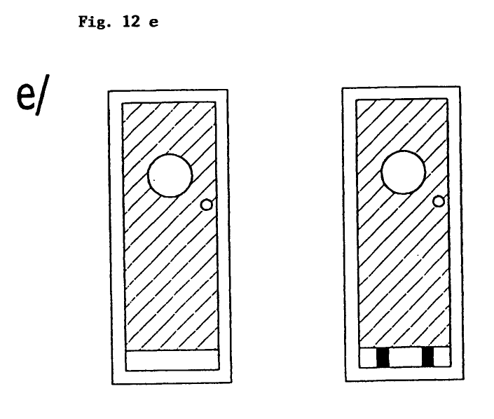

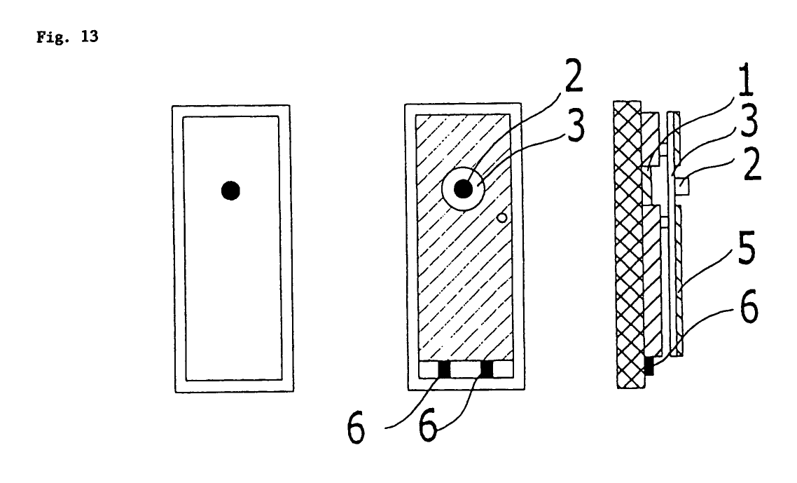

Sensor is made in the same way as in the case of pressure sensor. But in the last step the hole for breathing is not blinded there. There is also a step, in which a mass of inertia, which causes the changes of membrane deflection because of inertial forces is sticked on the membrane (see FIG. 13). The sensor is schematically represented on the FIG. 13, where 1 is the first electrode of capacitor, 2 is a mass of inertia, 3 is a membrane implemented according to the invention which forms the second electrode of capacitor, 5 is sensor covering layer, 6 are contacts for sensor connecting.

### Example 13

Action Element of Membrane Pump

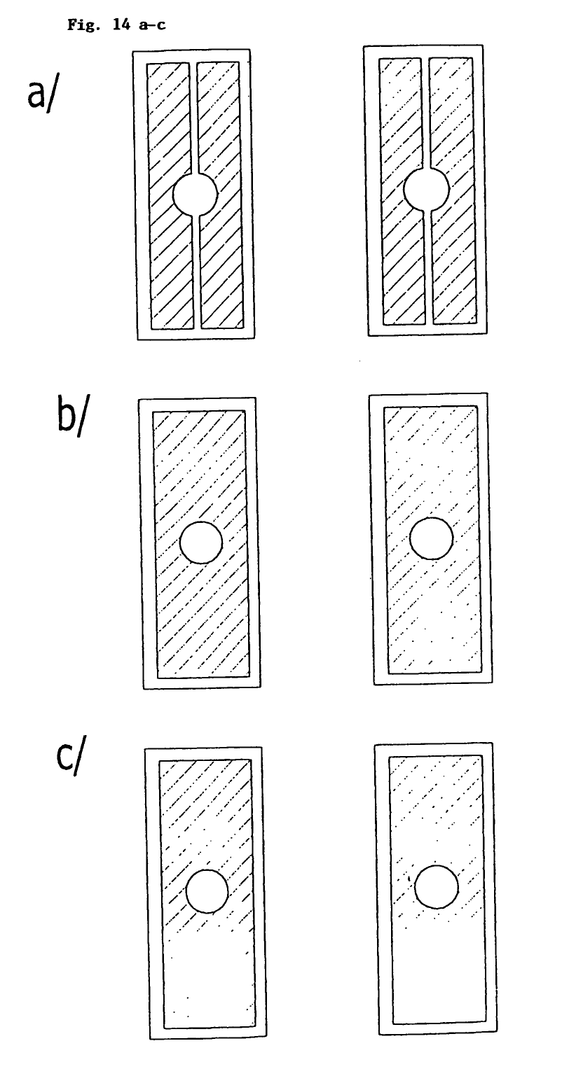

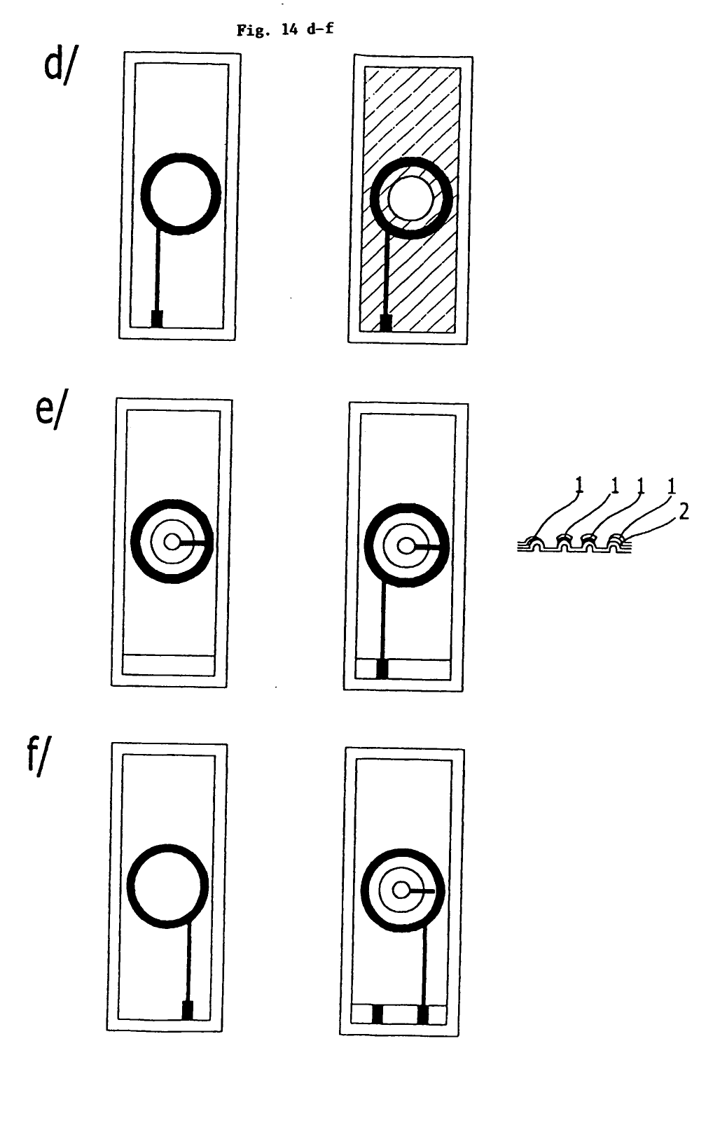

The action element of membrane pump can be made using a process according the FIG. 14. In the first step (a) (see FIG. 14a) a structure of input and output channel and internal volume of pump are printed. The pumping is caused by the change of internal volume. In the next step the membrane from polyethylene terephthalate nucleopor with pores size of 1 μm and thickness of 20 μm according to the invention provided with a hole is applied. The membrane is overprinted by dielectric material layer (see FIGS. 14b and 14c). This step finishes preparation of the structure of supplying channels and pumping space. In the next step (d) (FIG. 14d) the conductive layer which creates a supply to the piezoelectric membrane is printed. In the next step (e) (see FIG. 14e) piezoelectric membrane is inserted. The membrane at the FIG. 14e is a pre-formed metal membrane, which is perforated in the way according to the invention, which enables good features after inserting to the printed material. On the concave parts of the membrane piezo-ceramic and a further conductive layer are printed. The membrane changes its shape because of electric field inserted on the piezo-ceramic.

In the next step (f) the supplying connection to the other electrode of membrane is printed (see FIG. 14f). Finally in the last step (g) (see FIG. 14g) the whole structure is covered by covering layer, which stiffens and to encapsulates the structure. By applying alternating current to the supply it is possible to reach the change of pump working volume and after possible connection with the valve to reach the pumping of gas or liquid.

### Example 14

Backward Valve

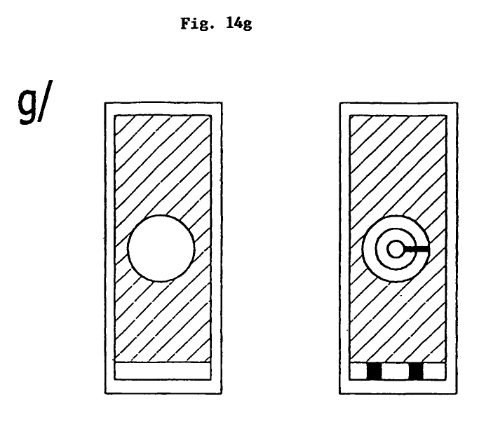

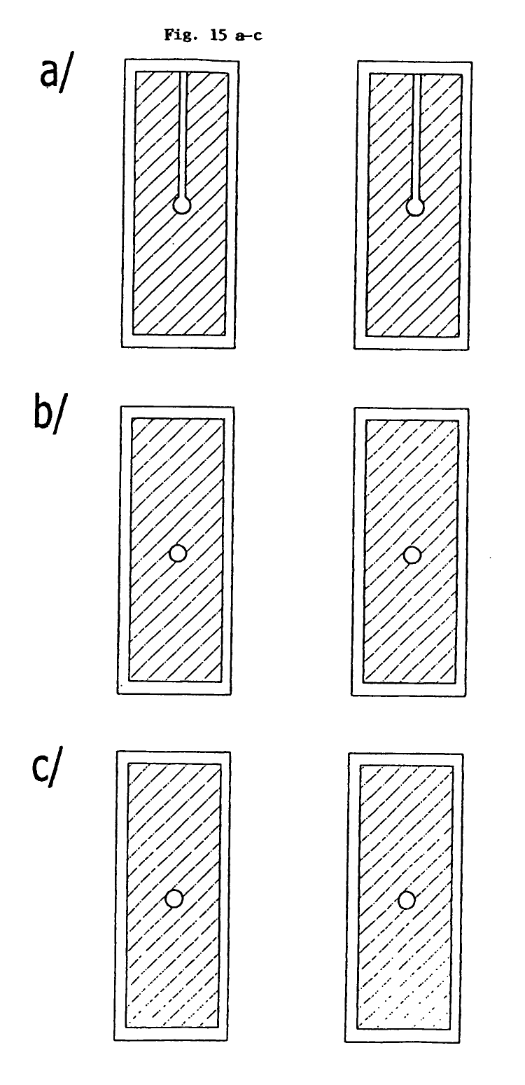

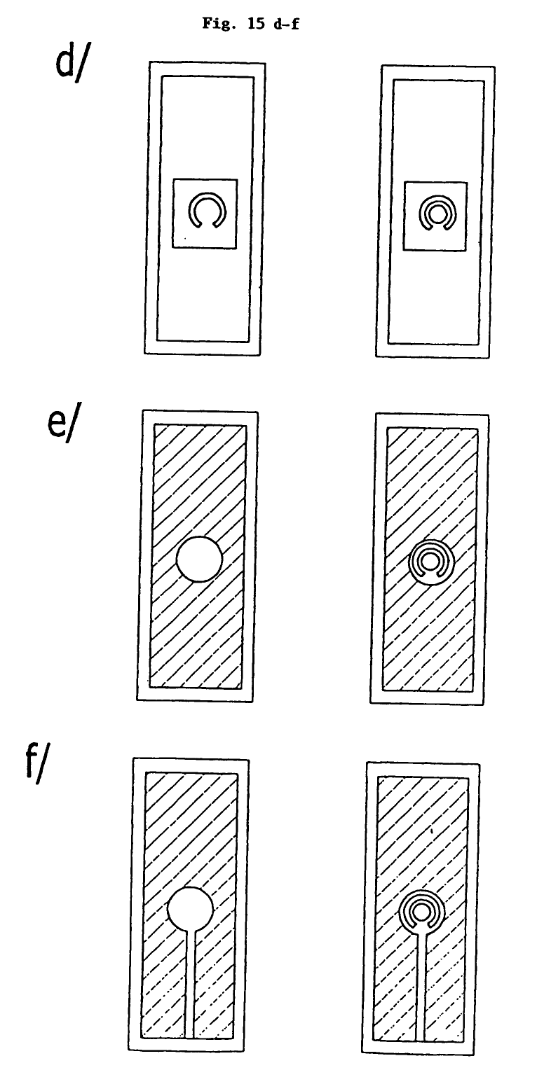

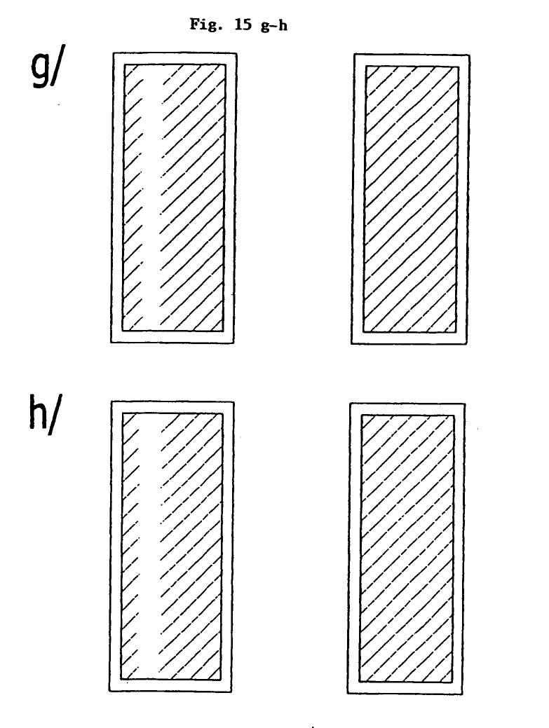

On FIG. 15 there is the backward valve production scheme. In the first step (a) the geometric structure of supplying channel is printed (see FIG. 15a). In the second step (b) the structure is covered by polyethylene terephthalate nucleopor with membrane with pores size of 1 μm and a thickness of 20 μm (see FIG. 15b) and it is overprinted by another layer (FIG. 15c), thus the structure of the supplying channel is finished. In the next step (d) a membrane made for example from nickel thin film having a thickness of 50 μm, partly perforated in a shape of membrane valve is applied (see FIG. 15d). In the next step (e) a layer, which allows the flap valve movement and hardens flap attachment is printed (see FIG. 15e). In the following step (f) the geometric structure of the output channel is printed (FIG. 15f). It is covered by polyethylene terephthalate nucleopor membrane, size 1 μm and thickness 20 μm (FIG. 15g). The production is finished by printing of the covering layer (h), which will finish the input and output microchannel (FIG. 15h) and hardens the whole structure. The production is finished by placing of the input and output mouthpiece.

### Example 15

Membrane Pump

By the combination of backward valve according to example 14 and active pump element according to the example 13 it is possible to prepare an electric membrane pump, powered through piezoelectric element (see FIG. 16).

A liquid or gas enter to the pump by mouthpiece 1, than proceed through backward valve 2, the preparation of which is described in the example 15, to the space, where volume is changed by piezoelectric membrane 3 (see FIG. 14). The valve 2 is closed by membrane with piezoceramic and by pressure enhancement, the valve 4 opens and a liquid is pushed out of the pump.

It is obvious, that through the combination of above mentioned examples it is possible to reach the creation of other more complicated devices. According to example 15 the connection of pump, capillary, input diffusion barrier and detector it is possible to create a method flow injection analysis. By the connection of pump and filter it is possible to create an active filter unit. It is obvious, that there exists a whole range of other significant devices, which can be miniaturized with the use of the method according to the invention and by the connection of above mentioned examples of use.

The next example shows the use of the new technology according to the invention for combination of thick layer technology with microelectronic element.

### Example 16

Capillary Electrophoresis on Si Chip with the Sample Preparation

There are known systems, where a capillary electrophoresis structure is realized on Si chip. The disadvantage of those systems is in the fact that they need a very careful preparation of the sample and that the resultant analyses are sometimes more expensive than classical analyses with the use of macro analytic devices. On the other hand a technology using directly Si chips has significant advantages. They are: higher dimensional precision, better chemical properties, better parameters from the point of possible impurities, which influence the measurement.

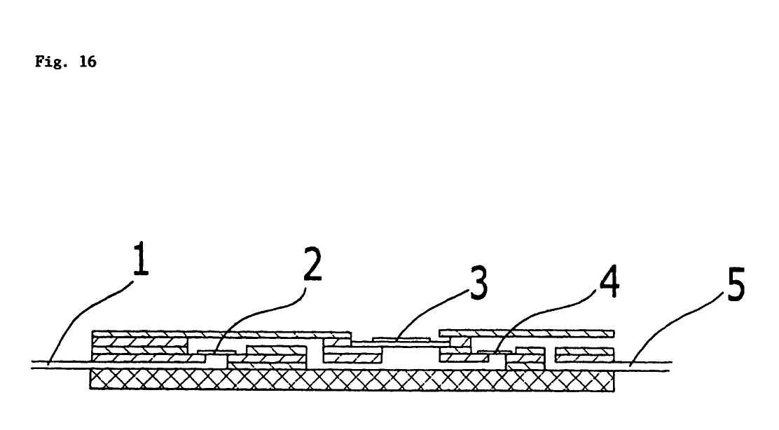

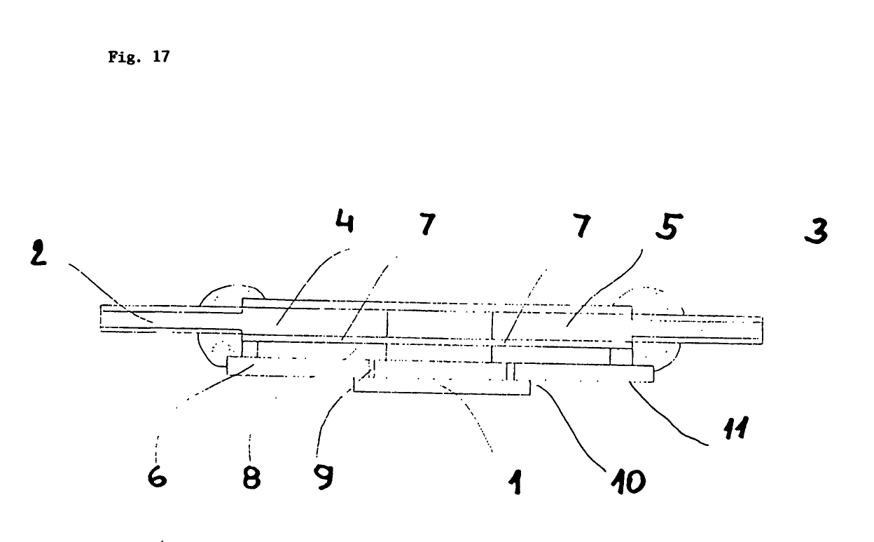

The way of production according to the invention allows to overcome the disadvantage of complicated preparation of a sample without any influence on the positive properties of Si chip in the way, which allows to integrate the chip to the carrier with filter elements, which allows sample preparation. Impurities which can influence the measurement cannot penetrate into the Si chip and into its microchannels (app. 11 μm). An example of such a system is on FIG. 17.

On the ceramic substrate 6 the structure of input channels 1 is printed, armed by input mouthpieces 2 and output of little channels 5 armed by output mouthpieces 3. This structure brings and leads liquids to the measuring element, prepared on Si chip 1. In the bottom of the input and output channels a membrane 7 is integrated in the way according to the invention. By the passage through the membrane the impurities are removed and the sample is collected in the microchannel 8, from where it is lead through the small hole in the ceramic to the chip input 1. The outputting liquid is lead through the hole 10 to the output channel 11 from where it runs through the membrane 7 to the output 3. The membrane can be partly removed in the place of the output channel 5, due to which a lower hydrodynamic resistance is achieved.

### Example 17

Microchemical Reactor (Lab on Chip)

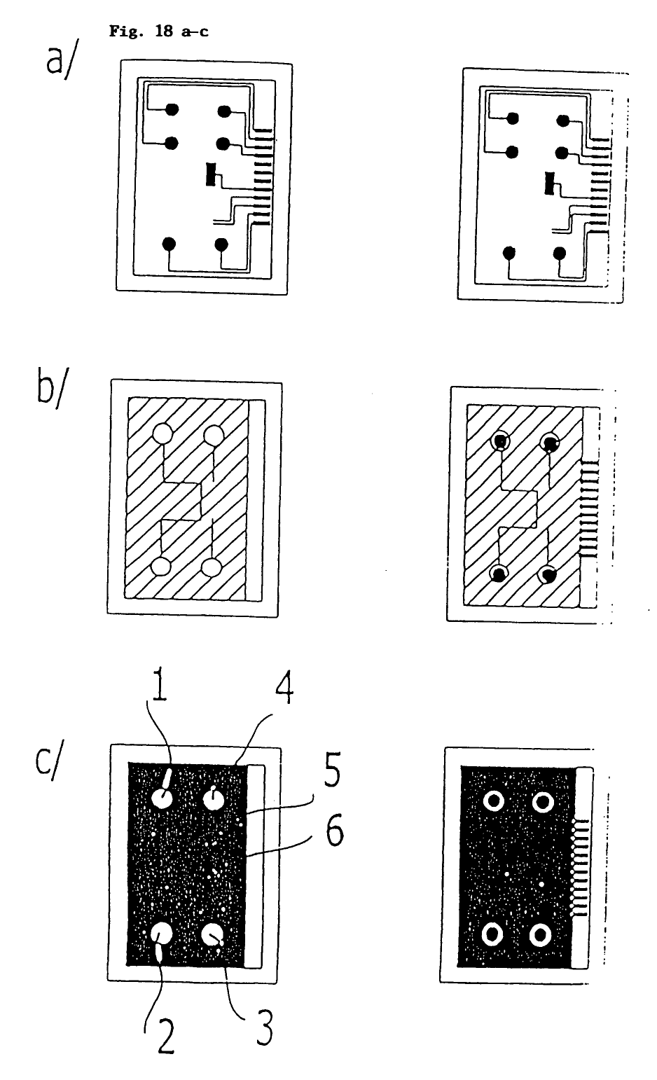

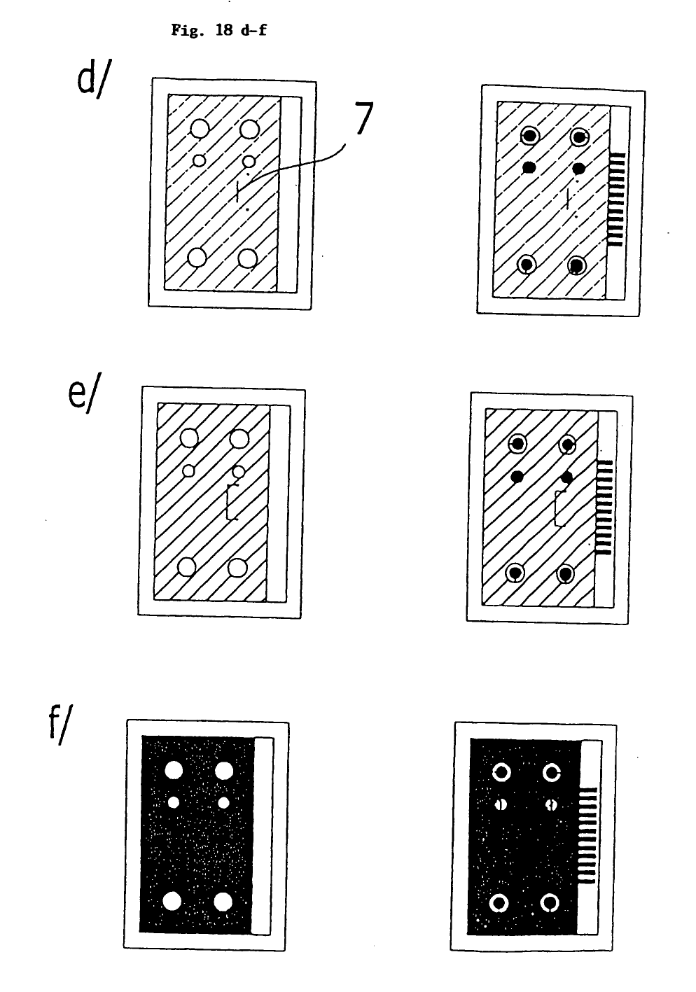

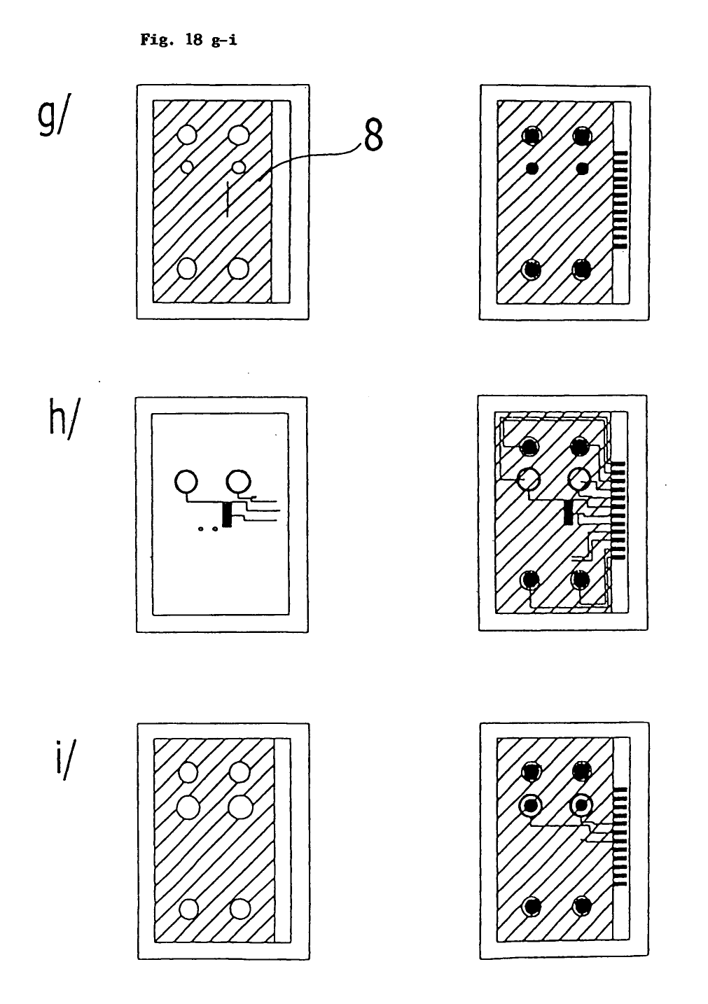

The basic electrode structure is printed on a corundum pad (see FIG. 18a). Channel structure is printed using dielectrical paste in the (b) step (FIG. 18b). The membrane of polyethylene terephthalate nucleopor with pores size of 1 μm and thickness of 10 μm with 6 holes is applied in step (c) (FIG. 3c). The holes 1-4 allow to access to the channel among inputs 1, 2, 3, 4. The holes 5 and 6 allow the penetration of the substance to the higher layers, which will be prepared in the next steps.

The dielectric layer is printed in the next step (d), which creates the ceiling of the channel between inputs 1 and 2. At the point 7 the channel ceiling is going through (FIG. 18d).

Channel for mixing solutions from channels 1-2 and 3-4 is created by dielectric paste printing in step (e) (FIG. 18e).

Another membrane of polyethylene terephthalate nucleopor with pores size of 1 μm and of thickness 10 μm, providing the holes and creating the ceiling of the mixing channel is applied in the step (f) (FIG. 18f).

The creating of the upper channel ceiling is finished by the print of a layer in the step (g). The space 8 is prepared for applying of electrode for electroosmotic filling of both working channels and electroosmotic mixing (FIG. 18h-step (h)).

The preparation is finished by the print of covering layer, which closes the whole structure. The arisen microchannels can be provided with mouthpieces, as mentioned earlier in the previous examples (step (i)-FIG. 18i).

### Example 18

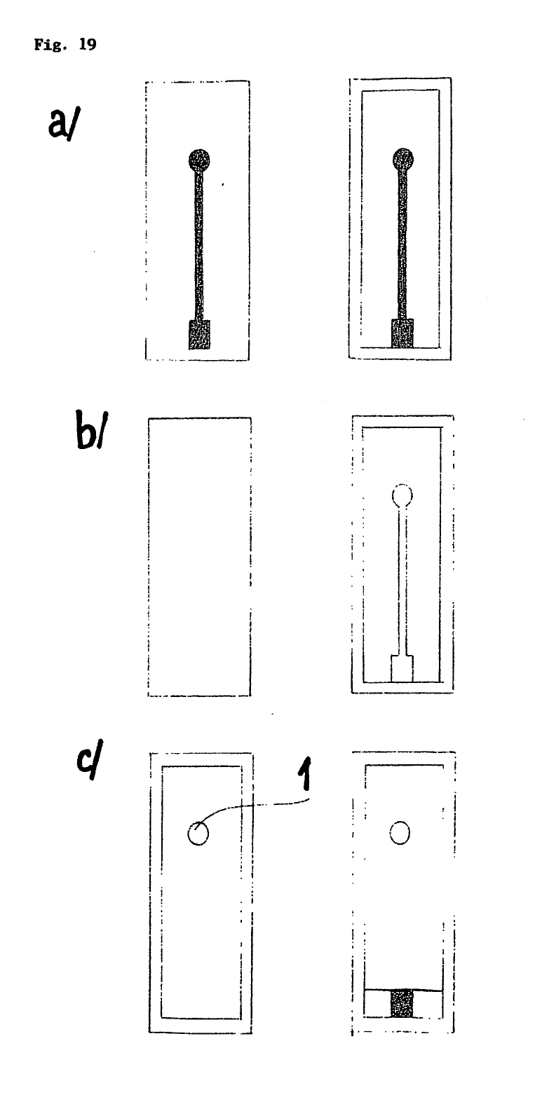

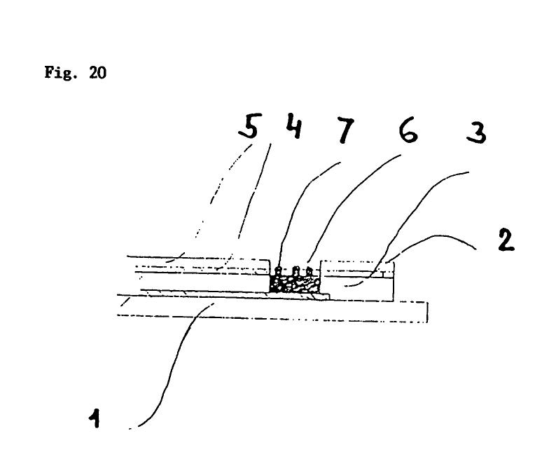

The way of producing the mercury microelectrode is shown on FIG. 19. In the first step the structure of the conductive electrode and conductive pathways are printed (see FIG. 19a). In the next step the structure is covered by a membrane according to the invention e.g. a membrane of polyethylene terephthalate with a thickness of 20 μm and a pore size of 10 μm (see FIG. 19b). In the last step the whole structure is covered by a dielectric layer having holes above the working electrode 2. The finished electrode is submerged into mercury and after deaeration of the space between the working electrode and the membrane it is filled with mercury. A cross-sectional view of the finished electrode is on FIG. 20. The electrode 2 lies on the ceramic pad 1. The space above the electrode 2 is created by the print of the layer 3 and covered by the membrane 4 according to the invention, which is fixed by the layer 5. The space 6 above the electrode is filled with mercury, which on the outer area of the membrane creates a field of mercury microelectrodes 7.

### Example 19

When a biosensor is constructed the problem how to create a defined bioactive membrane often arises. If the biosensor is prepared according to example 18 with the difference that the space above the electrode is filled with a bioactive material instead of mercury, an electrode with defined bioactive layer can be prepared.

1. Components with three-dimensional structure, prepared by thick film printing technology, characterized in that between the printed layers is inserted at least one membrane.

2. Components with three-dimensional structure, prepared by thick film printing technology, according to claim 1, characterized in that the membrane is present at least in a part of the final product.

3. Components with three-dimensional structure, prepared by thick film printing technology, according to claim 1, characterized in that the membrane is provided with holes.

4. Components with three-dimensional structure, prepared by thick film printing technology, according to claim 1, characterized in that the membrane is made of a compact non-porous material, which is in the place of membrane contact with printed layer perforated in such a way that the smallest distance between the holes is smaller than the quintuple of the printed layer thickness.

5. Components with three-dimensional structure, prepared by thick film printing technology, according to claim 4, characterized in that the membrane is made of metal.

6. Components with three-dimensional structure, prepared by thick film printing technology, according to claim 1, characterized in that the membrane has pores having the size of from 50 μm to 10 nm and a thickness of 1-200 micrometer.

7. Components with three-dimensional structure, prepared by thick film printing technology, according to claim 6, characterized in that the membrane is made of polyethylene terephthalate perforated by neutrons with pore diameters of 5-0.051 μm and a thickness of 2-20 μm.

8. Components with three-dimensional structure, prepared by thick film printing technology, according to claim 2, characterized in that the membrane is made of a material decomposable by heat.

9. Components with three-dimensional structure, prepared by thick film printed technology, according to claim 8, characterized in that the membrane is made of cellulose acetate with a pore diameter of 1-0.0011 μm and a thickness of 0.1-50 μm.

10. Method of producing components with three-dimensional structure thick film technology by print, according to claim 1, characterized in that, that between some of the printed layers are inserted membranes.

11. Method of producing components with three-dimensional structure thick film technology by print, according to claim 10, characterized in that the print is carried out by screen printing.

12. Method of producing components with three-dimensional structure thick film technology by print, according to claim 10, characterized in that, there are inserted membranes having a pore size of from 50 μm to 10 nm.

13. Method of producing components with three-dimensional structure thick film technology by print, according to claim 11, characterized in that the inserted membrane is made of the same material as the screen printing paste binder.

14. Method of producing components with three-dimensional structure thick film technology by print, according to claim 11, characterized in that the inserted membrane is made of a material decomposable by heat and the membrane is present only in a part of the final product.

15. Method of producing components with three-dimensional structure thick film technology by print, according to claim 11, characterized in that the inserted membrane is made of a chemically decomposable material and the membrane is present only in a part of the final product.

16. Method of producing components with three-dimensional structure thick film technology by print, according to claim 12, characterized in that the inserted membrane is prepared of polyethylene terephthalate perforated by neutrons with pore diameters of 5-0.05 μm and thickness of 2-20 μm.

17. Method of producing components with three-dimensional structure thick film technology by print, according to claim 14, characterized in that, the inserted membrane is prepared from cellulose acetate with pore diameters of 1-0.001 μm and a thickness of 0.1-10 μm.

18. Method of producing components with three-dimensional structure thick film technology by print, according to claim 10, characterized in that the inserted membrane is provided with gaps necessary for the further technological steps.

19. Method of producing components with three-dimensional structure thick film technology by print, according to claim 10, characterized in that the inserted membrane is prepared from a compact non-porous material, which is in the contact place of membrane with printed layer perforated in such a way, that the smallest distance between the holes is smaller than quintuple of the printed layer thickness.

20. Method of producing components with three-dimensional structure thick film technology by print, according to claim 10, characterized in that the inserted membrane is made of metal.
